(19) United States
(12) Patent Application Publication
(10) Pub. No.: US 2008/0251111 A1
(43) Pub. Date: Oct. 16, 2008

(54) THERMOELECTRIC ENERGY CONVERSION

(76) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/733,681

(22) Filed: Apr. 10, 2007

(51) Int. Cl. H01L 31/024

(52) U.S. Cl. 136/201; 136/212; 136/255

(57) ABSTRACT

A thermoelectric power generator includes a thermoelectric pile in a chamber. A window admits light and/or heat radiation such as solar radiation into the chamber, which is absorbed in a radiation absorbing body in thermal contact with a first side of the thermoelectric pile, whereby the temperature of the first side is raised. A second side of the thermoelectric pile is in thermal contact with the wall of the chamber, which is a heat sink to maintain the second side at a lower temperature. The temperature difference produces a voltage difference at electrical contacts to the thermoelectric pile, which is capable of powering electrical devices.

### BACKGROUND

1. Field of Invention

This invention generally relates to energy conversion systems and methods and, more particularly, to a solar powered thermoelectric generator.

2. Related Art

In many industrial processes a considerable quantity of heat energy is generated that is discarded as an unused byproduct. Conventional methods for removing or eliminating this heat may be through evaporation or heat exchange, eventually to the environment. Discarded heat energy is a cost of production that contributes to production cost inefficiency and may be measured as a direct cost of energy. It would be desirable to recapture and use such wasted energy.

Solar cells are a conventional source of electrical power in numerous applications, particularly where the cost of energy delivery or power requirement does not justify the investment in infrastructure. An example is a source of electrical power derived from sunlight in an at-sea application, where standard power generation is not available and power requirements may not justify conventional generation methods (i.e., oil or coal fired power generators). However, solar cells are responsive to a limited portion of the visible and near- infrared spectrum, whereas the solar spectrum reaching the surface of the earth is considerably broader.

Therefore, there is a need for power generation from solar and other radiation sources that takes more advantage of an available radiation spectrum that is independent of fossil or other conventional energy sources.

### SUMMARY

The present invention applies the well-known principles of operation of thermoelectric devices to conversion of light and/or heat radiation energy for useful production of electrical power in a thermoelectric power generator (TPG).

In one embodiment, a thermoelectric power generator includes a chamber having a thermoelectric pile contained within, where one surface of the pile is in physical and thermal contact with the inner surface of the chamber wall. A radiation absorbing body is in physical and thermal contact with an opposing surface of the thermoelectric pile. An optically transparent window enclosing the chamber on at least one face of the chamber admits radiation toward the radiation absorbing body, heating one side of the pile, thereby causing the pile to produce an electromotive force. Electrical wires connected to opposing terminals of the thermoelectric pile connect provide voltage and current to power the external device.

In a second embodiment, the heat absorbing body of the thermoelectric power generator described may further include an internal cavity to hold a first heat absorbing fluid.

In a third embodiment, the chamber wall of the thermoelectric power generator may further include an internal cavity in the chamber wall to hold a second heat absorbing fluid.

In a fourth embodiment, either or both of the fluids may be circulated through access ports between their respective cavities and the exterior of the thermoelectric generator.

In a fifth embodiment, the circulating fluids may be provided by external sources to maintain a temperature difference between opposing sides of the thermoelectric pile, thereby causing the thermoelectric generator to produce electrical power with or without radiation energy incident on the heat absorbing body.

In a sixth embodiment, a thermoelectric generator includes a flotation device coupled to the generator to enable the generator to float on water. The thermoelectric generator further includes a weight coupled to the bottom portion of the chamber wall of the generator, and may be configured to conduct heat from the chamber wall to the water.

In a seventh embodiment, a method of converting light radiation and heat to electricity includes a thermoelectric pile in a chamber receiving light radiation energy through a window on a radiation absorbing body in physical and thermal contact with one side of a thermoelectric pile and/or receiving heat energy from a fluid circulated to an internal cavity of the heat absorbing body. The thermoelectric pile, being in physical and thermal contact with the chamber wall, which is maintained at a lower temperature, generates an electromotive force to power an external device.

### BRIEF DESCRIPTION OF THE DRAWINGS

FIG. 1 illustrates one example of a Seebeck Effect thermoelectric couple.

FIG. 2 illustrates one example of a Seebeck Effect thermoelectric pile.

FIG. 3A is an exemplary graph illustrating the transmission characteristics of quartz (SiO₂).

FIG. 3b is an exemplary graph illustrating the transmission characteristics of potassium bromide (KBr).

FIG. 4 illustrates one embodiment of a thermoelectric power generator, in accordance with the present disclosure.

FIG. 5 illustrates a second embodiment of a thermoelectric power generator, in accordance with the present disclosure.

FIG. 6 illustrates a third embodiment of a thermoelectric power generator, in accordance with the present disclosure.

FIG. 7 illustrates a fourth embodiment of a thermoelectric power generator, in accordance with the present disclosure.

Embodiments of the present invention and their advantages are best understood by referring to the detailed description that follows. It should be appreciated that like reference numerals are used to identify like elements illustrated in one or more of the figures.

### DETAILED DESCRIPTION

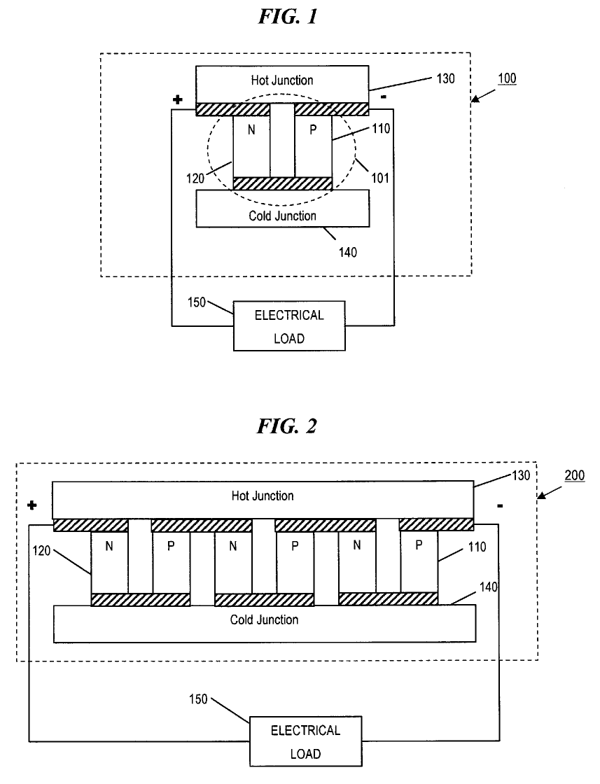

The concept of thermoelectric generation is well known. FIG. 1 illustrates a typical Seebeck Effect thermoelectric couple. A thermoelectric device 100 for electrical power generation usually involves using conventional thermoelectric couples 101, i.e., pairs of P and N doped semiconductor “pellets” 110 and 120, respectively, of materials such as, for example, bismuth/telluride.

The performance of thermoelectric couple 101 is based on well known thermoelectric generation principles, commonly known as the Seebeck effect, which involves producing a current in a closed circuit of two dissimilar materials, i.e., N doped pellets 110 and P doped pellets 120, forming two junctions, where one junction is held at a higher temperature (hot junction 130) than the other junction (cold junction 140).

The elevated temperature at hot junction 130 drives electrons in N doped pellet 120 toward cold junction 140 and drives “holes” in P doped pellet 110 in the same direction, i.e., toward cold junction 140. Since “holes” moving in one direction is equivalent to electrons moving in the opposite direction, the induced direction of charge movement, i.e., current, around a closed circuit is the same. Thus, a net voltage difference develops at the two terminals (+ and −) of couple 101, which may be applied to an external load 150.

Thermopiles are generally rated to produce a maximum current at a given voltage for a known temperature difference T2-T1. Terminal wires connected to the thermopile may be connected to provide an effective amount of voltage and current to electrical load 150 at its stated ratings, which may be, for example, a motor, lamp or other direct current (DC) electrical load, a battery for charging and storing electrical energy, or a converter for generation of alternating current (AC) to supply devices so adapted to operate. Other types of electrical load 150 may also be employed.

A corresponding Peltier effect is the inverse of the Seebeck effect. The Peltier effect involves the heating or cooling of the thermocouple junctions by a driving current from an external source.

FIG. 2 shows a thermoelectric pile 200, which comprises a plurality of couples 101 connected electrically in series and thermally in parallel. Connecting couples 101 in series electrically results in producing a larger net additive voltage. Connecting them in parallel contact between a temperature differential assures a uniformity and maximum thermal differential across each couple 101, resulting in the largest voltage difference per couple 101. In combining the couples into thermopiles 200, a greater variety of sizes, shapes, operating currents, operating voltages, and ranges of voltage and current generating capacity becomes available between the two terminals (+ and −).

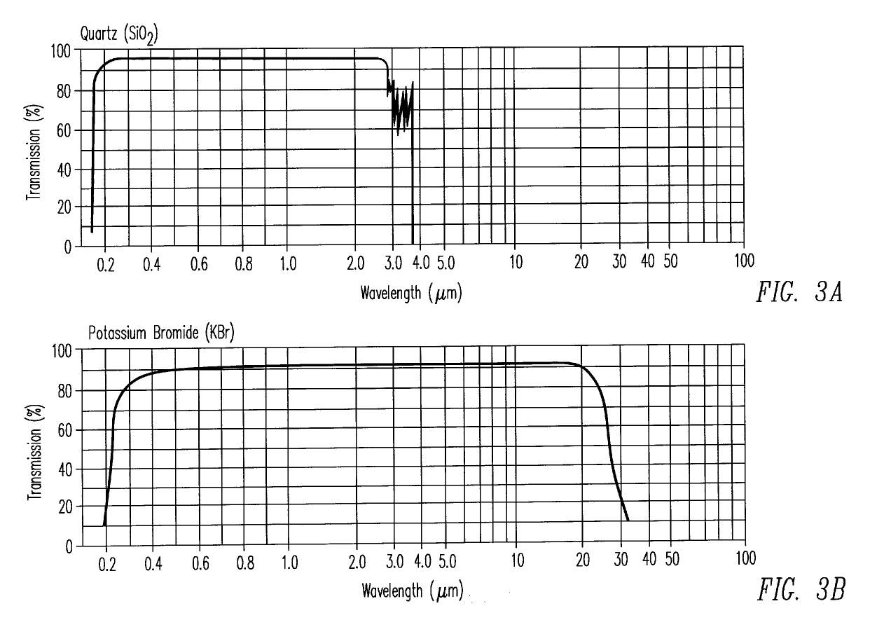

In various embodiments presented below, the heat source for the thermoelectric generation may be any heat source, including any generated, excess, wasted, and/or recyclable heat source, and including solar energy. It may be advantageous to contain thermopile 200 in a chamber with a window for admitting light and heat radiation to be absorbed by hot junction 130. A window material may be chosen for its efficient transparency to a broad range of light wave radiation. For example, FIG. 3A is a graph of a transmission efficiency of quartz (SiO₂), which is effective over wavelengths from approximately 200 nanometers to approximately 3 micrometers. Potassium bromide (KBr) transmission, shown in FIG. 3B, is effective from approximately 250 nanometers to approximately 25 micrometers. Numerous other materials exhibit similar transparency over a useful range of wavelengths.

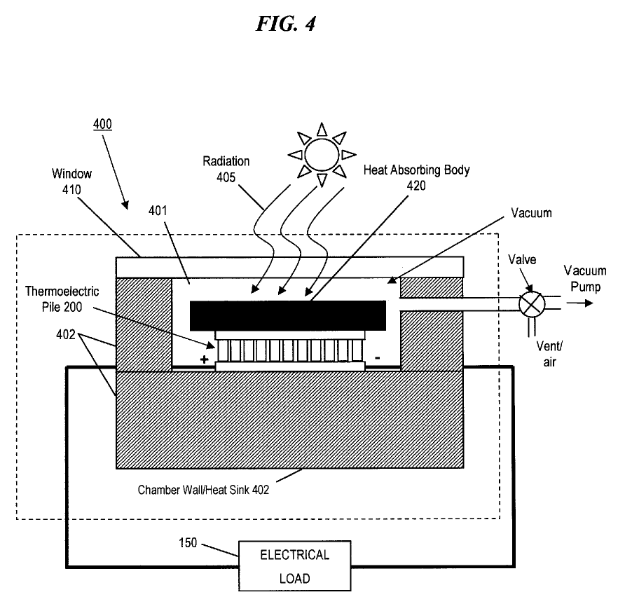

FIG. 4 illustrates an embodiment of a thermoelectric power generator 400 according to the present disclosure. The radiation source, for example, may be the sun. In one embodiment, thermoelectric pile 200 is mounted in a chamber 401 including a window 410 to permit sunlight or other radiation 405 to pass through. In one embodiment, the transparency of the window spans as broad a wavelength spectrum as possible to admit a maximum amount of energy to pass, but typically includes the range from ultraviolet to infrared.

A portion of thermopile 200 facing window 410 through which radiation 405 enters is in intimate contact with a heat absorbing body 420 composed of or coated with a material that efficiently absorbs radiation 405. The absorbed energy in heating body 420 establishes an elevated temperature on the contacting portion of thermopile 200.

The opposing side of thermopile 200 is in intimate physical contact with a bottom wall 402 of chamber 401 to enable thermal contact. The bottom and sides walls of chamber 401 are preferably highly thermally conductive and in intimate physical and thermal contact with each other or they may comprise a unitary structure, and which serve substantially as a heat sink at a lower temperature than heat absorbing body 420. Chamber 401 may be configured to serve as a passive heat sink, whereby the outer walls 402 of chamber 401 are in intimate contact with other structures and materials adapted to passively or actively conduct heat away or otherwise maintain a temperature that is lower than that of absorbing body 420.

For example, in a space-borne application, chamber 401 may be attached to radiative fins (not shown) that are shielded and facing away from direct exposure to the sun. The fins may then substantially radiate any accumulated energy to the vacuum of space, maintaining a thermodynamic equilibrium with the surrounding space, i.e., at a lower temperature. In an ambient application, a similar structure would establish equilibrium with the atmospheric temperature through radiative and conductive heat transfer using, for example, fins or similar structures adapted for efficient heat rejection.

Chamber 401 may be evacuated with a vacuum pump (not shown) to reduce convective transfer of heat from absorbing body 420 to chamber walls 402, thereby maintaining the maximum thermal differential between absorbing body 420 and heat sinking chamber walls 402. This, in turn, provides a maximum thermal differential between the two opposing sides of thermopile 200, and consequently, a maximum voltage difference generation. In a space-borne application, this is particularly beneficial, since no energy need be expended to produce a relative vacuum in the chamber, thereby being totally passive.

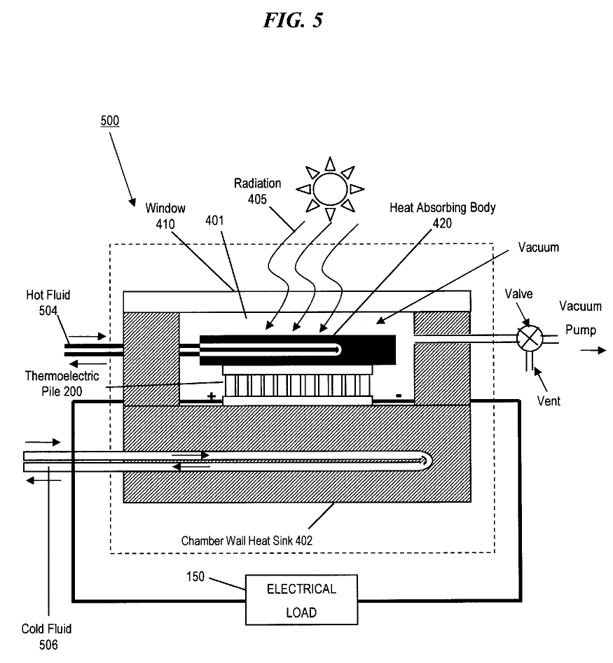

FIG. 5 illustrates another embodiment of a thermoelectric power generator 500, wherein fluids 504 heated in absorbing body 420 may be circulated out of chamber 401 for one or more purposes, as will now be described. Excess heat generated by other processes, such as manufacturing, may be circulated to pass through heat absorbing body 420 via fluids 504 to elevate or maintain its temperature. Thus, heat energy from other sources that may otherwise be wasted, may be recycled to assist or provide for thermoelectric power generation. Reciprocally, since it may be advantageous to maintain the temperature differential across thermopile 200 at a fixed value, and at a fixed absolute temperature, circulation of fluid 504 may be used to remove excess heat in order to limit the maximum temperature of heat absorbing body 420.

Furthermore, a cold fluid 506 at a lower temperature (i.e., heat sink fluid) may be circulated out of the body of chamber 401 to maintain cold junction 140 at a selected temperature lower than hot junction 130. For example, both hot fluid 504 and cold fluid 506 may be circulated to mediate and maintain a stable temperature differential between heat absorbing body 420 and heat sink/chamber wall 402, thus assuring a constant voltage potential difference, since this differential is directly dependent on temperature differential. Alternatively, or in combination with this mediating function, the fluid 504 and cold fluid 506 may be coupled to an external system whereby excess heat generated in thermoelectric power generator 500 is used to perform additional non-electrical work such as, for example, environmental heating or cooling, that would otherwise be wasted in overheating generator 500. Thus, additional work may be extracted from generator 500 in addition to electrical power.

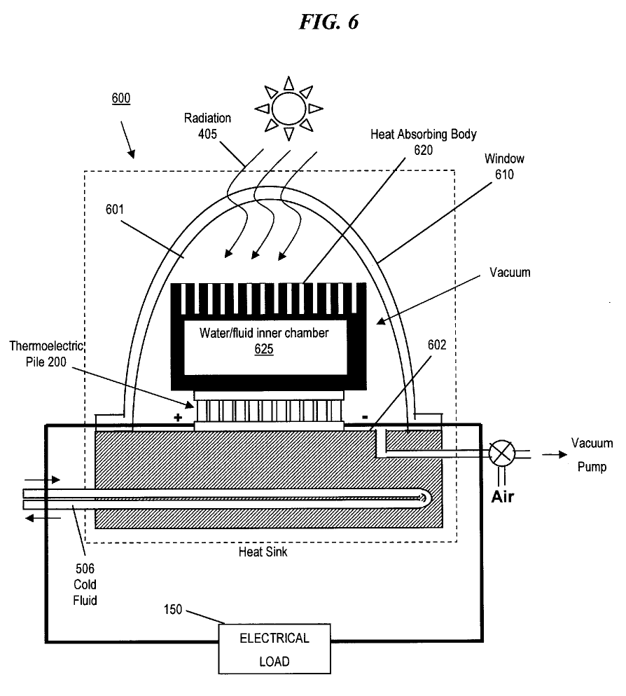

FIG. 6 illustrates an embodiment of a thermoelectric power generator 600 in which a heat absorbing body 620 may further include fins or a complex surface facing a window 610 to increase the surface area exposed to radiation 405, thereby making it a more efficient absorber. Additionally, the surface fins or other structures may be configured to improve the omni-directional efficiency for absorption of radiation. Absorbing body 620 may further include an inner chamber 625 filled with a fluid or it may be, alternatively, a substantially solid body. In either case, heat absorbing body 620 may comprise one or more materials (solid and/or fluid) with a large thermal capacity, whereby the large thermal mass enables large heat storage—in effect a thermal heat battery, in analogy to an electric battery—resulting in a more stable temperature and consequently more stable voltage and power output by generator 600. The large thermal mass of absorbing body 620 may, by analogy to an electric battery, provide continued power generation by generator 600 when radiation 405 is absent or insufficient.

Window 610 may be of various shapes such as, for example, a bell jar, to accommodate the more complex structure of absorbing body 620, thereby requiring a variation in the detailed shape of chamber 601 and the chamber walls 602 which serve a heat sink function for cold junction 140. As described before, generator 600 may be coupled to a vacuum pump to evacuate chamber 601 to minimize thermal convective loss of heat energy from heat absorbing body through any path other than thermoelectric pile 200. Chamber wall 602 may provide the heat sinking function, as described earlier, and may be in intimate contact with additional external heat transfer and rejection structures (not shown), as described earlier. Chamber wall 602 may also include a fluid circulating system to remove excess heat, as described earlier, to maintain a stable temperature differential between opposing sides of thermoelectric pile 200, thereby maintaining stable voltage and power characteristics.

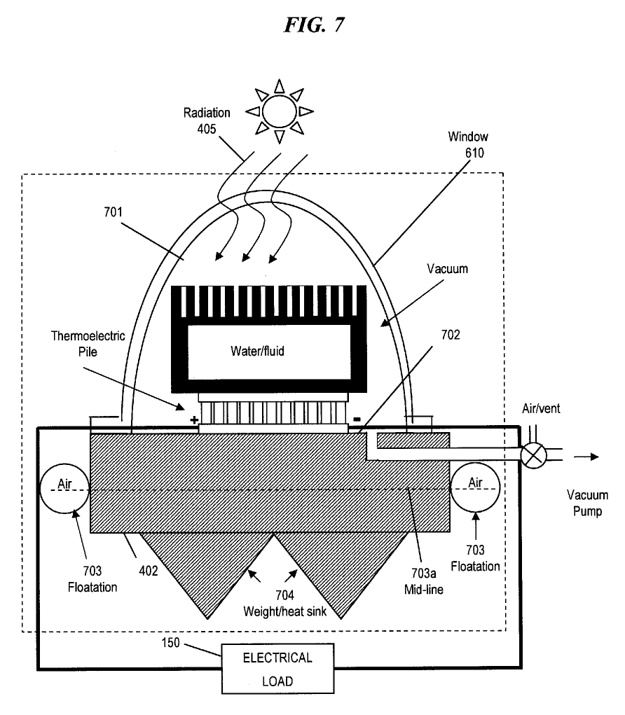

FIG. 7 illustrates another embodiment of a thermoelectric power generator 700, which may be configured for supplying power in a water-borne application. Here, the water, which may be ocean, lake, river, or any body of water, is in contact with chamber wall 702. Generator 700 may further include a floatation device 703 to insure buoyancy of generator 700. Chamber wall 702 may further include an additional weight 704 that simultaneously may provide vertical orientation control by establishing a center-of-gravity of generator 700 below a mid-line 703a of floatation device 703. Weight 704 may also be adapted to provide additional surface area and thermal mass for conducting excess heat to the water from cold junction 140, in order to maintain the thermal differential across thermoelectric pile 200 for electrical operational stability. Chamber 701 may be evacuated, as previously described, to increase thermodynamic efficiency.

The above-described embodiments of the present invention are merely meant to be illustrative and not limiting. For example, it will thus be obvious to those skilled in the art that various changes and modifications may be made without departing from this invention in its broader aspects. Therefore, the appended claims encompass all such changes and modifications as fall within the true spirit and scope of this invention.

What is claimed is:

1. A thermoelectric power generator, comprising:
a chamber having at least one wall with an inner surface;
a thermoelectric pile contained within the chamber and having a first surface and an opposing second surface, wherein the first surface is in thermal contact with the inner surface of the at least one wall;
a radiation absorbing body in thermal contact with the second surface of the thermoelectric pile;
an optically transparent window enclosing the chamber on at least one face of the chamber, wherein radiation impinges on the radiation absorbing body to increase the temperature of one surface of the thermoelectric pile; and
electrically conductive wires connected to opposing terminals of the thermoelectric pile configured to connect to an external electrical device and provide voltage and/or current to the external device.

2. The thermoelectric power generator of claim 1, further comprising an access port to the chamber for evacuating the chamber.

3. The thermoelectric power generator of claim 1, wherein the radiation absorbing body comprises a flat planar surface configured to receive the radiation.

4. The generator of claim 1, wherein the radiation absorbing body comprises a plurality of distinct surfaces configured to receive the radiation.

5. The thermoelectric power generator of claim 1, wherein the radiation absorbing body comprises an internal cavity to hold a first heat absorbing fluid.

6. The thermoelectric generator of claim 1, wherein the radiation absorbing body comprises a heat energy storage battery for causing the thermoelectric pile to produce an electromotive force.

7. The thermoelectric power generator of claim 1, wherein the at least one of chamber wall comprises an internal cavity to hold a second heat absorbing fluid.

8. The thermoelectric power generator of claim 5, wherein the radiation absorbing body comprises an access port configured for circulating the first heat absorbing fluid between the cavity of the radiation absorbing body and the exterior of the thermoelectric power generator.

9. The thermoelectric power generator of claim 7, wherein the at least one chamber wall comprises an access port configured for circulating the second heat absorbing fluid between the cavity contained in the chamber wall and the exterior of the thermoelectric power generator.

10. The thermoelectric power generator of claim 5, wherein the at least one of chamber wall comprises an internal cavity to hold a second heat absorbing fluid.

11. The thermoelectric power generator of claim 10, wherein the first heat absorbing fluid and the second heat absorbing fluid are provided by external processes to generate thermoelectric power when radiation energy is absent or insufficient to provide electrical power.

12. The thermoelectric power generator of claim 1, wherein the window is planar.

13. The generator of claim 1, wherein the window is curved.

14. The generator of claim 1, wherein the window is bell-shaped.

15. The thermoelectric power generator of claim 1, wherein the window is transparent to radiation in the wavelength range between 200 nanometers and 12 micrometers.

16. The thermoelectric power generator of claim 1, further comprising:
a flotation device coupled to the chamber wall to enable the generator to float on water; and
a weight coupled to a bottom portion of the chamber wall.

17. The thermoelectric power generator of claim 16, wherein the weight is configured to conduct heat from the chamber wall to the water.

18. A method of generating thermoelectric power comprising:
absorbing energy in a heat and radiation absorbing body contained in chamber to increase the temperature of the heat and radiation absorbing body;
heating a first side of a thermoelectric pile in physical and thermal contact with the radiation absorbing body;
maintaining a lower temperature at a second side of the thermoelectric pile in physical and thermal contact with an inner surface of a wall of the chamber, wherein the chamber wall is configured to conduct heat away from the thermoelectric pile; and
generating an electromotive force at contacts attached to the thermoelectric pile due to a temperature differential between the first and the second sides.

19. The generator of claim 18, further comprising:
accessing the electromotive force with wires attached to the contacts to provide power to an external device.

20. A method of generating thermoelectric power comprising:
receiving energy into a sealed chamber cavity;
absorbing the energy in an energy absorbing body in the chamber cavity to increase the temperature of the body;
heating a first side of a thermoelectric pile in contact with the energy absorbing body by thermal conductance between the radiation absorbing body and the thermoelectric pile;
maintaining the temperature of a second side of the thermoelectric pile at a lower temperature by thermally contacting the second side with an inner surface of a wall of the chamber cavity, wherein the chamber is a wall is configured to enable removing heat by thermal conductance;
generating a voltage at contacts attached to the thermoelectric pile due to the temperature differential between the first and the second sides; and
accessing the voltage via conductive electrical wires passing from the interior of the chamber to the exterior.

21. The method of claim 20, wherein the absorbing comprises storing heat energy in radiation absorbing body.

22. The method of claim 20, wherein the receiving comprises receiving radiation energy from an external source through a transparent window.

23. The method of claim 20, wherein the receiving comprises receiving heat energy from a fluid circulated between the energy absorbing body and an external source.

24. The method of claim 20, wherein the heat is removed from the chamber wall by heat sinking the chamber wall to an external body at a selected temperature.

25. The method of claim 24, wherein the external body is water in which the generator floats.

26. The method of claim 20, wherein the heat is removed from the chamber wall by circulating a fluid between a cavity internal to the chamber wall and the exterior of the generator.

27. The method of claim 20, wherein the maintaining further comprises evacuating the chamber.
